(19) United States
(12) Patent Application Publication
(10) Pub. No.: US 2009/0058688 A1
(43) Pub. Date: Mar. 5, 2009

(54) DISAMBIGUATION OF KEYPAD TEXT ENTRY

(76) Inventor: Karl Ola Thorn, Lund (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(21) Appl. No.: 11/845,150

(22) Filed: Aug. 27, 2007

(51) Int. Cl. H03K 17/94; H04M 1/02

(52) U.S. Cl. 341/22; 455/575.1

(57) ABSTRACT

A mobile device comprises a keypad comprising a plurality of keys for text entry into a text based application. Each key may represent at least two alpha numeric characters. A word layer disambiguation engine generates a list of textonyms for each of a sequence of words entered via user activation of the keys. A phrase layer disambiguation engine selecting a single selected one of the textonyms for each word in the sequence of words. The selected one of the textonyms may be the textonym that meets selection criteria that is a function of one of: i) the word entered by the user prior to the textonym; ii) the word entered by the user following the textonym; iii) an identification of an application into which the user is entering the words; and iv) identification of a recipient to which the words will be sent.

### TECHNICAL FIELD OF THE INVENTION

The present invention relates to input of text on a mobile device user interface and, in particular, to disambiguation of text input on a mobile device with an ambiguous interface.

### DESCRIPTION OF THE RELATED ART

Contemporary portable devices, including mobile telephones, portable data assistants (PDAs), and other mobile electronic devices typically include embedded email, text messaging, chat, notes, and other text based applications in addition to traditional communication applications such as mobile telephony.

In each of these applications, text information comprising a combination of alpha numeric characters is input through a user interface of the portable device such as a typical telephone keypad, a full QWERTY miniature keypad, or a touch screen emulating a keyboard.

In contemporary mobile devices the most common user interface configuration comprises keys corresponding to the ten digits “0” through “9” plus additional keys such as “#” and “*”. Each of the keys corresponding to one of the ten digits may also be allocated a number of characters. For example, the key corresponding to the digit “2” is also associated with the characters “A, B, C”.

From a alpha numeric text perspective, this ten digit user interface may be referred as an ambiguous keyboard because the same key is utilized to input each of the digit “2” and letters “A”, “B”, and “C”. As such, to facilitate entry of text information, there are two well known techniques for disambiguating characters typed on such a ten digit keyboard—“multi-tap” and “predictive text”.

In the “multi-tap” system, the user may press each key a number of times depending on the letter that the user wants to enter. For example, when a text based application is active on the portable device, pressing the key corresponding to the digit “2” once gives the character “A”, pressing the key twice gives the character “B” and pressing the key three times gives the character “C”. Usually, there is a predetermined amount of time within which the multiple keys strokes may be entered. This may allow for the key to be re-used for another letter when necessary. Further, pressing the key for a certain period of time usually gives the corresponding number. For instance, in the above example, pressing the key for two seconds may give the digit “2”.

In the “predictive text” system, a predictive text dictionary is used for disambiguating a sequence of key strokes. More specifically, when using a portable device having a predictive text editor, the user may enter a word into a text based application by pressing the keys corresponding to each character of the word exactly once. For example, if the user desires to enter the word “HELLO”, then he or she does this by pressing the keys “4” (which corresponds to ambiguous text input of “G”, “H” or “I”), “3” (which corresponds to ambiguous text input of “D”, “E” or “F”), “5” (which corresponds to ambiguous text input of “1”, “K” or “L”), “5” and “6” (which corresponds to ambiguous text input of “M”, “N” or “O”).

The sequence is referenced to the predictive text dictionary to disambiguate the sequence of keys pressed by the user into one or more candidate words. In more detail, the dictionary associates frequency of use statistics with various words/key sequences such that candidate words may be chosen and typically presented to the user as a combination of: i) a “default” word which is the most likely word corresponding to the sequence of keys based on frequency of use; and ii) other candidate words presented in an order of the most likely word corresponding to the sequence of keys to least likely.

If the “default” word is the word desired by the user, the user simply continues typing. If the “default” word is not the word the user desires, the user typically scrolls through a list of the other candidate words to select the desired word. Contemporary portable devices typically include a a five way navigation control to facilitate such scrolling and selection by way of moving a cursor or highlight bar on a display screen of the user interface.

Predictive text systems may be more desirable than multi-tap systems because of the reduced number of key strokes required to enter a particular word. However, one of the problems with predictive text editors may be that there are a large number of keystroke combinations which map to multiple words all used with relatively equal frequency. Such words may be referred to as textonyms in that they may be represented by the same combination of keystrokes. In theory, a user may resolve this ambiguity by scrolling the candidate words and selecting the desired word. However, in practice many users type “heads down” meaning that the user watches the keyboard only without referencing the screen to verify that the predictive text system has actually selected the desired word as the “default” word. As such, by continuing to type without verifying the “default” word, the default word becomes part of the text regardless of whether it is the actual word desired by the user. This can result in unintended consequences if and when the text is sent to a remote reader.

As such, what is needed is an improved portable device comprising an improved system and method for disambiguating text input for purposes of improving the probability that a default word selected by a disambiguating system is the word desired by the user inputting the text.

### SUMMARY

A first aspect of the present invention comprises a mobile device with a keypad comprising plurality of keys. Each key may represent at least two alpha numeric characters for entry of text into a text based application.

A word layer disambiguation engine may generate a list of textonyms for each of a sequence of words entered via user activation of the keys. A phrase layer disambiguation engine may select a single selected one of the textonyms for each word in the sequence of words. Or, stated another way, the phrase layer disambiguation engine may distinguish between a single selected one of the textonyms and the remaining textonyms.

The selected one of the textonyms may be the textonym that meets selection criteria that is a function of one of: i) the word entered by the user prior to the textonym; ii) the word entered by the user following the textonym; iii) an identification of an application into which the user is entering the words; and iv) identification of a recipient to which the words will be sent.

In a first sub embodiment, the mobile device may further comprise a statistic database storing, for each of a plurality of word sequences, data representing a frequency of use. In this sub embodiment, the phrase layer disambiguation engine may select a single selected one of the textonyms by selecting the textonym that creates a sequence of words this is more frequently used than other sequences of words derivable from the list of textonyms.

In a second sub embodiment, the mobile device may further comprise a contact database associating each of a plurality of individuals with: i) a transmission address for sending a text based message to such individual; and ii) a contact classification.

In this sub embodiment, the phrase layer disambiguation engine may select a single selected one of the textonyms by selecting the textonym that creates a sequence of words this is more frequently used than other sequences of words when entering text for sending to a recipient within the contact classification.

In a third sub embodiment, the mobile device may further comprise a database identifying a plurality of word combinations as undesirable. In this sub embodiment, the phrase layer disambiguation engine may select a single selected one of the textonyms by selecting the textonym that creates a sequence of words other than a one of the plurality of word combinations identified as undesirable.

In a fourth sub embodiment, the mobile device may further comprise a grammar rules database identifying rules for sequencing words. In this sub embodiment, the phrase layer disambiguation engine may select a single selected one of the textonyms by selecting a textonym that creates a sequence of words that complies with the rules for sequencing words.

In a fifth sub embodiment, the phrase layer disambiguation engine may select a single selected one of the textonyms by: i) sending an indication of the list of textonyms and at least one of the word entered by the user prior to the textonym and the word entered by the user following the textonym to a remote disambiguation server; and ii) receiving an identification of the selected one of the textonyms from the remote disambiguation server.

In a sixth sub embodiment, the list of textonyms may further comprise a proper spelling for an improperly spelled word within the sequence of words entered via user activation of the keys. In this sub embodiment, the phrase layer disambiguation engine may select a single selected one of the textonyms by selecting a textonym that is a proper spelling.

In a seventh sub embodiment, the list of textonyms may further comprise a proper word for a contracted word within the sequence of words entered via user activation of the keys. In this sub embodiment, the phrase layer disambiguation engine may select a single selected one of the textonyms by selecting a textonym that is a proper word.

A second aspect of the present invention comprises a method of disambiguating text entered into a mobile device via a keypad comprising a plurality of keys. Again, each key may represent at least two alpha numeric characters. The method may comprise generating a list of textonyms for each word of a sequence of words entered via user activation of the keys and selecting, for each word, a single selected one of the textonyms. The selected one of the textonyms may be the textonym that meets selection criteria that is a function of one of: i) the word entered by the user prior to the textonym; ii) the word entered by the user following the textonym; iii) an identification of an application into which the user is entering the words; and iv) identification of a recipient to which the words will be sent. The single selected one of the textonyms may be displayed on a display screen of the portable device.

In a first sub embodiment, selecting a single selected one of the textonyms may comprise: i) referencing a statistic database storing, for each of a plurality of word sequences, data representing frequency of use; and ii) selecting the textonym that creates a sequence of words this is more frequently used than other sequences of words derivable from the list of textonyms.

In a second sub embodiment, selecting a single selected one of the textonyms may comprise: i) referencing a contact database associating each of a plurality of individuals with a transmission address for sending a text based message to such individual and a contact classification; and ii) selecting the textonym that creates a sequence of words this is more frequently used than other sequences of words when entering text for sending to a recipient within the contact classification.

In a third sub embodiment, selecting a single selected one of the textonyms may comprise: i) referencing a database identifying a plurality of word combinations as undesirable; and ii) selecting the textonym that creates a sequence of words other than a one of the plurality of word combinations identified as undesirable.

In a fourth sub embodiment, selecting a single selected one of the textonyms may comprise: i) referencing a grammar rules database identifying rules for sequencing words; and ii) selecting a textonym that creates a sequence of words that complies with the rules for sequencing words.

In a fifth sub embodiment, selecting a single selected one of the textonyms may comprise: i) sending an indication of the list of textonyms and at least one of the word entered by the user prior to the textonym and the word entered by the user following the textonym to a remote disambiguation server; and ii) receiving an identification of the selected one of the textonyms from the remote disambiguation server.

In a sixth sub embodiment, the list of textonyms may further comprise a proper spelling for an improperly spelled word within the sequence of words entered via user activation of the keys. As such, selecting a single selected one of the textonyms may comprise selecting the textonym that is a proper spelling.

In a seventh sub embodiment, the list of textonyms may further comprise a proper word for a contracted word within the sequence of words entered via user activation of the keys. As such, selecting a single selected one of the textonyms may comprise selecting a textonym that is a proper word.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

It should be emphasized that the term “comprises/comprising” when used in this specification is taken to specify the presence of stated features, integers, steps or components but does not preclude the presence or addition of one or more other features, integers, steps, components or groups thereof.

### BRIEF DESCRIPTION OF THE DRAWINGS

FIG. 1 is a diagram representing a mobile device in accordance with an exemplary embodiment of the present invention;

FIG. 2 is a flow chart representing exemplary operation of a disambiguation engine in accordance with an exemplary embodiment of the present invention;

FIG. 3 is a table representing a statistic database device in accordance with an exemplary embodiment of the present invention;

FIG. 4 is a diagram representing exemplary disambiguation device in accordance with an exemplary embodiment of the present invention;

FIG. 5 is a table diagram representing an exemplary contact database device in accordance with an exemplary embodiment of the present invention;

FIG. 6 is a diagram representing an exemplary grammar rules database device in accordance with an exemplary embodiment of the present invention; and

FIG. 7 is a diagram representing exemplary disambiguation device in accordance with an exemplary embodiment of the present invention;

### DETAILED DESCRIPTION OF EMBODIMENTS

The term “electronic equipment” as referred to herein includes portable radio communication equipment. The term “portable radio communication equipment”, also referred to herein as a “mobile radio terminal” or “mobile device”, includes all equipment such as mobile phones, pagers, communicators, electronic organizers, personal digital assistants (PDAs), smart phones, GPS devices, mobile gaming devices, MP3 players, remote controls, or the like.

Many of the elements discussed in this specification, whether referred to as a “system” a “module” a “circuit” or similar, may be implemented in hardware circuit(s), a processor executing software code, or a combination of a hardware circuit and a processor executing code. As such, the term circuit as used throughout this specification is intended to encompass a hardware circuit (whether discrete elements or an integrated circuit block), a processor executing code, or a combination of a hardware circuit and a processor executing code, or other combinations of the above known to those skilled in the art.

In the drawings, each element with a reference number is similar to other elements with the same reference number independent of any letter designation following the reference number. In the text, a reference number with a specific letter designation following the reference number refers to the specific element with the number and letter designation and a reference number without a specific letter designation refers to all elements with the same reference number independent of any letter designation following the reference number in the drawings.

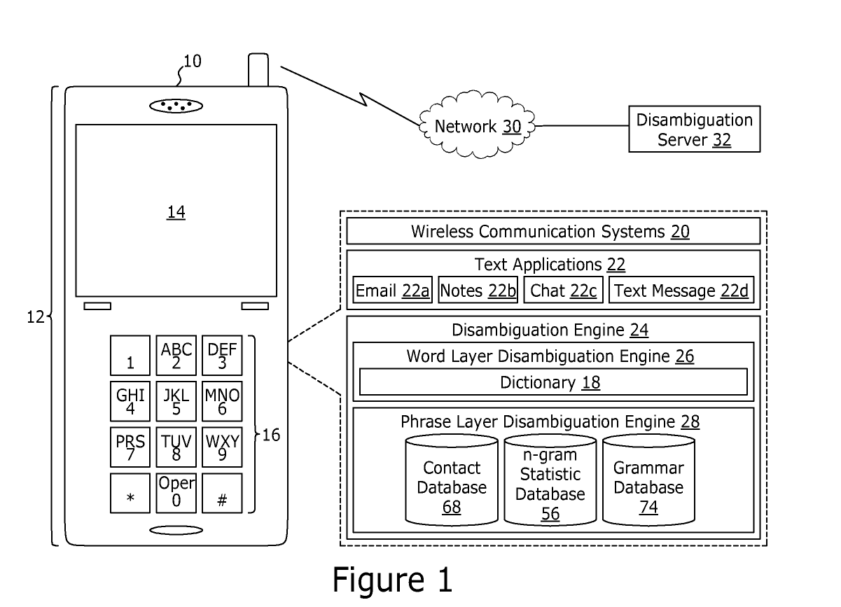

FIG. 1 represents an exemplary mobile device 10 in accordance with the present invention. The mobile device 10 may be implemented as a traditional mobile telephone, PDA, or other device as discussed in the first paragraph of this description. The exemplary mobile device 10 may include a user interface 12 comprising a combination of a display 14 and keypad 16 arranged in a typical 10-key telephony format (e.g. 0-9, * and #). In other embodiments, the user interface of the mobile device 10 may further, or alternatively, include the keypad 16 as a touch panel that either overlay the display 14 or is distinct form the display 14 and/or additional a keypad representing a full QWERTY keyboard.

The portable device 10 may further include: i) a wireless communication system 20 for wireless communication with remote systems over a service provider network 30—such as a mobile telephone network; ii) a plurality of text based applications 22 such as an email application 22a, a notes application 22b, a chat application 22c, and/or a text messaging application 22d.

In the embodiment wherein the keys of the keypad 16 are arranged in a typical telephony format, each key may also represent a plurality letters of the alphabet. For example, in English, each of the keys represents three letters with the 9 key representing letters “w”, “x”, “y”, and “z”. In other languages, each key 16 may represent a plurality of language specific letters. For example, in Swedish the 2 key represents “a”, “b”, “c”, “a”, and “a”. This enables a user of the portable device 10 to enter text into each of the text based applications 22 operating on the portable device 10 utilizing such keypad 16.

To facilitate text entry using the keypad 16, a disambiguation engine 24 is utilized for disambiguating a sequence of key strokes. In more detail, the user may enter a word into a text based application by pressing the key corresponding to each character of the word exactly once. For example, if the user desires to enter the word “hello”, then he or she does this by pressing the keys “4” (which corresponds to ambiguous text input of “g”, “h” or “i”), “3” (which corresponds to ambiguous text input of “d”, “e” or “f”), “5” (which corresponds to ambiguous text input of “j”, “k” or “l”), “5” and “6” (which corresponds to ambiguous text input of “m”, “n” or “o”).

The disambiguation engine 24 determines that the key strokes of 4-3-5-5-6 is the word hello versus other combinations of the ambiguous letters.

The disambiguation engine 24 of the present invention may comprise both a word layer disambiguation engine 26 and a phrase layer disambiguation engine 28. The word layer disambiguation engine 26 may reference the key strokes to a predictive text dictionary 18 to disambiguate the sequence of keys pressed by the user into one or more candidate words. If there are more than two candidate words, they may be referred to as textonyms in that the letters of the words comprise the same text strokes on the keypad 16.

The dictionary 18 may associate frequency of use statistics with various words/key sequences such that candidate words may be chosen. If textonyms exist, the plurality of textonyms may be provided to the phrase layer disambiguation engine 28 for disambiguation by distinguishing between a single selected one of the plurality of textonyms and remainder of the textonyms based on phrase layer selection criteria. The phrase layer selection criteria may be a function of at least one of: i) the word entered by the user prior to the textonym ii) the word entered by the user following the textonym; iii) an identification of an application into which the user is entering the words; and iv) identification of a recipient to which the words will be sent.

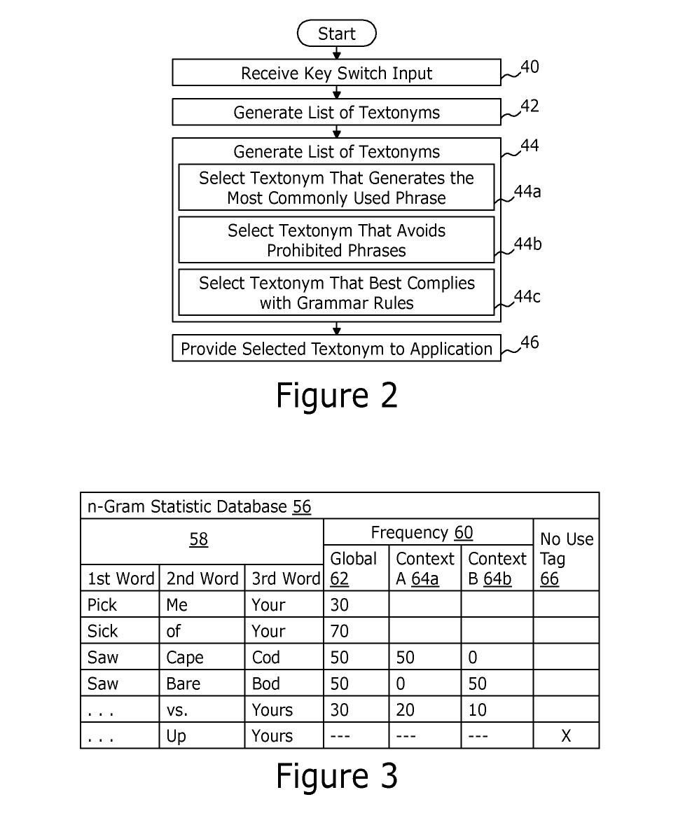

FIG. 2 depicts exemplary operation of the disambiguation engine 24 as represented in flow chart form. Turning to FIG. 2 in conjunction with FIG. 1, step 40 represents receiving user key entry of text via the keypad 16.

Step 42 represents the word layer disambiguation engine 26 referencing the dictionary 18 to disambiguate the keystrokes into candidate words and in each case wherein the key strokes may represent more than one candidate word—generate a list of textonyms for such sequence of key strokes.

Step 44 represents the phrase layer disambiguation engine 28 applying phrase layer selection criteria to determine a selected one of the textonyms. The selection criteria may be implemented in three aspects. In a first aspect 44a, an n-gram statistic database 56 may be referenced for applying selection criteria for phrase layer disambiguation based on at least one of: i) the word entered by the user prior to the textonym; and ii) the word entered by the user following the textonym.

Referring to FIG. 3, an exemplary n-gram statistic database 56 is represented in a table form. The n-gram statistic database 56 is illustrated as a 3-gram model for disambiguation based on statistical usage of three word combinations 58.

Associated with each three word combination 58 are frequency statistics 60. The frequency statistics may represent how often the three word combination 58 is used for purposes of comparison with frequency of use of other three word combinations 58 that may be derived from the same set of candidate words. For example, each of “pick me your” and “sick of your” may be derived from the same set of candidate words generated by key strokes 7425_{—}63_{—}9687.

The frequency statistics 60 may include global statistics 62 representing how often the a word combination 58 of three or more words is used globally meaning independent of the text application 22 into which the text is being typed and independent of the recipient of the text. Further the frequency statistics 60 may include context based statistics 64a-64b representing how often the three word combination 58 is used in each of a plurality of contexts.

It is envisioned that certain phrases may be utilized more often in certain text applications 22 than in others primarily because user's tend to use different applications for different types of communications. As such, each context 64a, 64b may each represent one or more of the text applications 22 such that usage statistics of the three word combination 58 as used in the particular one or more text applications 22. For example, context A 64a may represent frequency of usage in the email application 22a which context B 64b may represent frequency of usage in the chat application 22c and the text messaging application 22d.

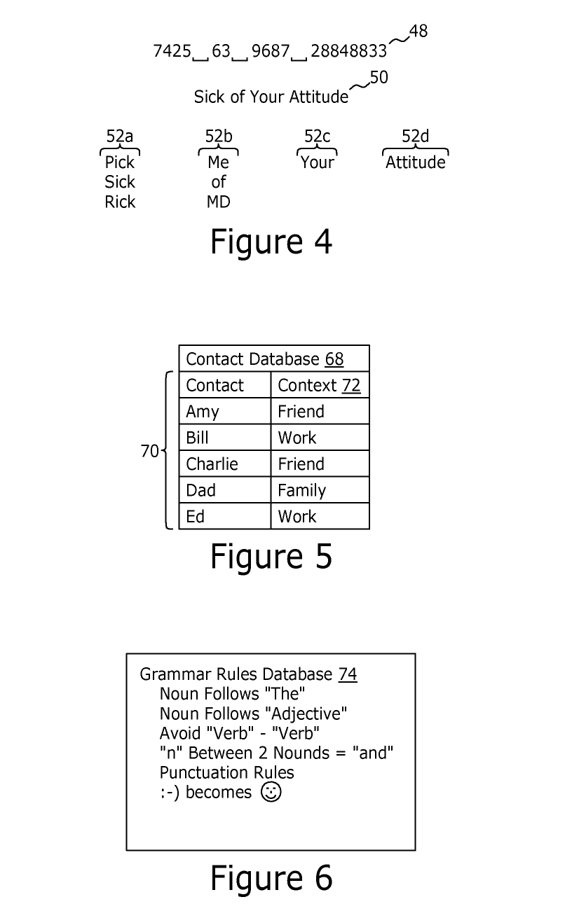

It is also envisioned that certain phrases may be utilized more often when communicating with certain people. As such, turning briefly to FIG. 5, each contact 70 in a contact database 68 may be associated with a context identifier 72. Example context identifiers 72 include “Friend”, “Work”, and “Family”. As such, returning to FIG. 4, each context 64a, 64b may each represent one or more of the context identifiers 72 such that usage statistics of the three word combination 58 as used when communicating with contacts within the context. For example, context A 64a may represent frequency of usage when communicating with contacts associated with “Work” and Context B 64b may represent frequency of usage when communicating with contacts associated with “Friend” and “Family”.

As such, in the first aspect 44a, applying selection criteria for phrase layer disambiguation based on at least one of: i) the word entered prior to the textonym; and ii) the word entered following the textonym may comprise selection of the textonym that yields the most commonly used phrase either globally or within the applicable context.

For example, turning to FIG. 4 in conjunction with FIG. 1 and FIG. 3, a user may enter a sequence of key strokes 48 with the intent that the keystrokes 48 represent the desired text 50 which is “sick of your attitude”.

As discussed with respect to step 42, the word layer disambiguation engine 26 references the dictionary 18 to disambiguate the keystrokes into words. The candidate words 52a for the digits 7, 4, 2, 5 may include “pick”, “sick”, and “Rick”. Further, in the absence of phrase layer disambiguation criteria, the word “pick” may be the selected candidate word as the dictionary 18 may include word layer statistics indicating that the word “pick” is most commonly used over “sick”. The candidate words 52b for the digits 6, 3 may include “me”, “of”, and “MD”. The candidate words 52c for the digits 9, 6, 8, 7 may include “your” without further textonyms. The candidate words 52d for the digits 2, 8, 8, 4, 8, 8, 3, 3 may include “attitude” without further textonyms.

Applying phrase layer disambiguation to determine the selected textonym that generates the most commonly used phrase may comprise comparing usage of each three word combination that can be assembled from the sequence of three candidate words 52a, 52b, and 52c to determining which combination has the most frequent usage either on a global bases or on a context basis wherein the context may be either based on the application 22 into which the text is being entered or the contact 70 to which the entered text will be transmitted.

In this example, even though the word “pick” may be more commonly used than the word “sick” at the word layer, at the phrase layer the three word combination “sick of your” is more commonly used than “pick me your”. As such, the selected textonyms associate with the more commonly used combination “sick of your”.

Referring again to FIG. 2, in a second aspect 44b, the selection criteria may comprise selection of the textonym that yields an acceptable phrase (e.g. avoids yielding an unacceptable phrase). It is recognized that certain words, for example certain well known 4-letter words, are not desirable to use. Further, it is recognized that certain combinations of acceptable words create phrases that are not desirable for use and should be avoided as being presented by the disambiguation engine 24. As such, the statistic database 56 (FIG. 3) may include a no use tag 66 associated with certain word combinations and determining the selected textonym that avoids prohibited phrases may comprise comparing the potential three word combinations to those with no use tags 66 and selecting a word combination that does not include such no use tag 66.

In a third aspect 44c, the selection criteria may comprise selection of the textonym that best complies with grammar rules. Turning briefly to FIG. 6, a grammar rules database 74 is represented. The grammar rules database 74 may store certain grammar rules, including but not limited to representation of: i) the word following the word “the” should be a noun; ii) the word following an adjective is most likely either another adjective or a noun with a string of adjectives ultimately ending with a noun; and iii) rules regarding avoiding use of two verbs in a row. As such, determining the selected textonym in this third aspect 44c may comprise determining the selected textonym that complies with the grammar rules.

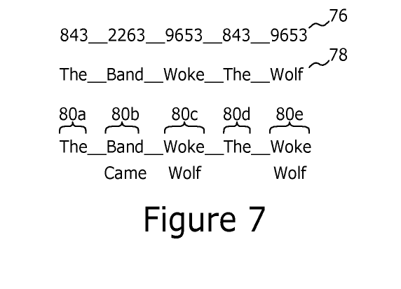

For example, referring briefly to FIG. 7, a user may enter a sequence of key strokes 76 with the intent that the keystrokes 76 represent the desired text 78 which is “the band woke the wolf”.

As discussed with respect to step 42, the word layer disambiguation engine 26 references the dictionary 18 to disambiguate the keystrokes into words. The candidate word 80a for the digits 8, 4, 3 is “the” without further textonyms. The candidate words 80b for the digits 2, 2, 6, 3 may include “band” and “came”. The candidate words 80c for the digits 9, 6, 5, 3, may include “woke” and “wolf”. The candidate words 80d for the digits 8, 4, 3 is “the” without further textonyms. The candidate words 80e for the digits 9, 6, 5, 3 may again include “woke” and “wolf”.

Application of the grammar rule that the word following the word “the” should be a noun indicates that the selected candidate word amongst candidate words 80b should be “band” because the word “band” can be a noun while the word “came” is not a noun. Similarly, the selected candidate word amongst the candidate words 80e should be “wolf” because the word “wolf” may be a noun while the word “woke” is not a noun.

Returning to FIG. 2, after operation of the phrase layer disambiguation engine 28 in any combination of the first aspect 44a, the second aspect 44b, and the third aspect 44c, the selected candidate word may be provided to the text application at step 46.

Referring again to FIG. 6, it is also envisioned that the grammar rules database 74 may be utilized to generate proper words from common abbreviations or misspellings. For example, the letter “n” is a commonly used abbreviation for the word “and”. As such, a grammar rule may indicate that use of the 6 key (representing “n”) between two nouns should be the word “and”. Grammar rules may also include punctuation rules and rules that provide for automated conversion of certain key sequences to certain symbols such as the key sequence of colon, end bracket (e.g. :)) converting to a smiley face [symbol] . Other grammar rules may indicate that a key sequence which could be a formal name be selected over other words when used at the beginning or end of a message where it is likely the name of the sender or the recipient.

Referring again to FIG. 1, as discussed, the portable device 10 may further comprise a wireless communication system 20 for communication within a service providers wide area network 30. As such, it is envisioned that a remote disambiguation server 32 may perform any combination of word layer or phrase later disambiguation as discussed with respect to the disambiguation engine 24.

It is further envisioned that such a remote disambiguation server 32 may have capabilities to developing a statistical database by aggregating usage amongst all users typing similar words or phrases and utilizing the disambiguation server 32 for disambiguation thereof.

As such, a further aspect of operation of the disambiguation engine 24 may comprise i) sending an indication of the list of textonyms (or other keystroke data) and at least one of the word entered by the user prior to the textonym and the word entered by the user following the textonym (or other key stroke data) to the remote disambiguation server 32; and ii) receiving an identification of the selected one of the textonyms from the remote disambiguation server.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. A mobile device comprising:
a keypad comprising a plurality of keys, each key representing at least two alpha numeric characters;
a word layer disambiguation engine generating a list of textonyms for each of a sequence of words entered via user activation of the keypad;
a phrase layer disambiguation engine selecting a single selected one of the textonyms for each word in the sequence of words, the selected one of the textonyms being the textonym that meets selection criteria that is a function of at least one of:
the word entered by the user prior to the textonym;
the word entered by the user following the textonym;
an identification of an application into which the user is entering the words; and
identification of a recipient to which the words will be sent.

2. The mobile device of claim 1, wherein each key represents at least two alpha numeric characters.

3. The mobile device of claim 2:
further comprising a statistic database storing, for each of a plurality of word sequences, data representing a frequency of use; and
wherein the phrase layer disambiguation engine selects a single selected one of the textonyms by selecting the textonym that creates a sequence of words this is more frequently used than other sequences of words derivable from the list of textonyms.

4. The mobile device of claim 2:
further comprising a contact database associating each of a plurality of individuals with:
a transmission address for sending a text based message to such individual; and
a contact classification;
the phrase layer disambiguation engine selects a single selected one of the textonym by selecting the textonym that creates a sequence of words this is more frequently used than other sequences of words when entering text for sending to a recipient within the contact classification.

5. The mobile device of claim 2:
further comprising a database identifying a plurality of word combinations as undesirable; and
the phrase layer disambiguation engine selects a single selected one of the textonyms by selecting the textonym that creates a sequence of words other than a one of the plurality of word combinations identified as undesirable.

6. The mobile device of claim 2:
further comprising a grammar rules database identifying rules for sequencing words; and
wherein the phrase layer disambiguation engine selects a single selected one of the textonyms by selecting a textonym that creates a sequence of words that complies with the rules for sequencing words.

7. The mobile device of claim 2, wherein the phrase layer disambiguation engine selects a single selected one of the textonyms by:
sending an indication of the list of textonyms and at least one of the word entered by the user prior to the textonym and the word entered by the user following the textonym to a remote disambiguation server; and
receiving an identification of the selected one of the textonyms from the remote disambiguation server.

8. The mobile device of claim 2, wherein:
the list of textonyms may further comprise a proper spelling for an improperly spelled word within the sequence of words entered via user activation of the keypad; and
the phrase layer disambiguation engine selects a single selected one of the textonyms by selecting a textonym that is a proper spelling.

9. The mobile device of claim 2, wherein:
the list of textonyms may further comprise a proper word for a contracted word within the sequence of words entered via user activation of the keypad; and
the phrase layer disambiguation engine selects a single selected one of the textonyms by selecting a textonym that is a proper word.

10. A method of disambiguating text entered into a mobile device via a plurality of keys, the method comprising:
receiving user input of a key sequence on a keypad;
generating a list of textonyms for each word of a sequence of words represented by the key sequence;
selecting, for each word, a single selected one of the textonyms, the selected one of the textonyms being the textonym that meets selection criteria that is a function of one of:
the word entered by the user prior to the textonym;
the word entered by the user following the textonym;
an identification of an application into which the user is entering the words; and
identification of a recipient to which the words will be sent.

11. The method of claim 10 wherein receiving user input of a key sequence comprises receiving user input of a key sequence wherein each key represents at least two alpha numeric characters.

12. The method of claim 11, wherein selecting a single selected one of the textonyms comprises:
referencing a statistic database storing, for each of a plurality of word sequences, data representing frequency of use; and
selecting the textonym that creates a sequence of words this is more frequently used than other sequences of words derivable from the list of textonyms.

13. The method of claim 11, wherein selecting a single selected one of the textonyms comprises:
referencing a contact database associating each of a plurality of individuals with:
a transmission address for sending a text based message to such individual; and
a contact classification; and
selecting the textonym that creates a sequence of words this is more frequently used than other sequences of words when entering text for sending to a recipient within the contact classification.

14. The method of claim 11, wherein selecting a single selected one of the textonyms comprises:
referencing a database identifying a plurality of word combinations as undesirable; and
selecting the textonym that creates a sequence of words other than a one of the plurality of word combinations identified as undesirable.

15. The method of claim 11, wherein selecting a single selected one of the textonyms comprises:
referencing a grammar rules database identifying rules for sequencing words; and
selecting a textonym that creates a sequence of words that complies with the rules for sequencing words.

16. The method of claim 11, wherein selecting a single selected one of the textonyms comprises:
sending an indication of the list of textonyms and at least one of the word entered by the user prior to the textonym and the word entered by the user following the textonym to a remote disambiguation server; and
receiving an identification of the selected one of the textonyms from the remote disambiguation server.

17. The method of claim 11, wherein:
the list of textonyms may further comprise a proper spelling for an improperly spelled word within the sequence of words entered via user activation of the keys; and
selecting the textonym that is a proper spelling.

18. The method of claim 11, wherein:
the list of textonyms may further comprise a proper word for a contracted word within the sequence of words entered via user activation of the keys; and
selecting a textonym that is a proper word.
